(19) United States
(12) Patent Application Publication
(10) Pub. No.: US 2008/0185725 A1
(43) Pub. Date: Aug. 7, 2008

(54) Semiconductor substrate

(75) Inventors: Wen Cheng Lee, Taichung (TW); Chien-Ping Huang, Taichung (TW); Yu-Po Wang, Taichung (TW); Wei-Chun Lin, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/011,854

(22) Filed: Jan. 30, 2008

(30) Foreign Application Priority Data
Feb. 6, 2007 (TW) 096104214

(51) Int. Cl. H01L 23/482

(52) U.S. Cl. 257/773; 257/E23.015

(57) ABSTRACT

A semiconductor substrate having a body and a plurality of finger pads formed thereon is disclosed. Each of the finger pads includes two expanding portions respectively and a connecting portion formed therebetween. The finger pads are alternately arranged on the body in a manner that one of the expanding portions of one of the finger pads is disposed in position corresponding to the connecting portion of an adjacent one of the finger pads, so as to reduce pitches between the finger pads horizontally and vertically, provide sufficient spaces for wire bonding, and prevent a wire bonder from mistakenly recognizing a lead trace coupled to the finger pad as another finger pad.

### FIELD OF THE INVENTION

The present invention relates to an electronic carrier board, and more particularly, to a substrate for use in a semiconductor package.

### BACKGROUND OF THE INVENTION

In order to meet ever-increasing demands for advanced electronic products with multi-functions, a ball grid array (BGA) type packaging technique is frequently employed and becomes very popular as such packaging technique is capable of providing a sufficient amount of input/out (I/O) connections for connecting high-density electronic components and electronic circuits.

Along with continuous improvements in semiconductor packaging technology, the amount and the density of I/O connections are drastically increased in a BGA package. In view of this, an increasing amount of finger pads corresponding to the amount of I/O connections must be formed on a substrate to act as external electrical connecting terminals of a semiconductor chip, so as to allow the semiconductor chip to be electrically connected external circuits through the finger pads by means of wire bonding.

A known layout of finger pads on a substrate, which is similar to what has been disclosed by U.S. Pat. Nos. 6,465,891 and 6,531,762, has a plurality of finger pads disposed around the periphery of a semiconductor chip at equal intervals, wherein a plurality of bonding wires are employed to respectively electrically connect bonding pads of the semiconductor chip to the finger pads of the substrate, so as to form external electrical connections of the chip.

The amount of I/O connections may be increased to improve electrical functionality of the semiconductor package, wherein the amount of the bonding pad of the chip and the finger pads of the substrate may be increased accordingly. However, in order to achieve such arrangement, pitches between the finger pads have to be reduced to a certain level. Moreover, the finger pads shall be disposed in position near the chip to shorten the length of the bonding wires, in order to improve electrical functionality and reduce production cost.

Referring to FIG. 1, a prior-art layout of finger pads on a substrate, which can shorten the length of bonding wires, is disclosed by U.S. Pat. No. 5,898,213. In the prior art, a plurality of finger pads 111 and its adjacent finger pads 112 are staggered around the periphery of a chip 12, wherein, hereinafter, the foregoing finger pads that are closer to the center of the chip 12 are referred as the first finger pads 111 and the ones that are further from the center of the chip 12 are referred as the second finger pads 112. Moreover, a plurality of bonding wires 13 are employed for electrically connecting bonding pads 122 on the chip 12 to the finger pads 111, 112 on the substrate. As the first finger pads 111 and the second finger pads 112 are disposed in a staggered pattern, the pitch distance Q between the finger pads 111, 112 is thus reduced, thereby reducing the length and the wire bonding distance of the bonding wires.

The foregoing technique may reduce the patch distance between the first finger pads 111 and the second finger pads 112. In practical implementation, a bonder is employed for connecting the chip 12 to the first finger pads 111 and then to the second finger pads 112 via bonding wires 13. However, because the size, shape and location of the second finger pads 112 are very close to that of lead traces of the first finger pads 111, the bonder can hardly distinguish the second finger pads 112 from the lead traces of the first finger pads 111, thereby frequently, mistakenly recognizing lead traces formed at the rear portions of the first finger pads 111 as the second finger pads 112 and erroneously bonding the bonding wires to the lead traces of the first finger pads 111 rather than the second finger pads 112 (such incorrect bonding is shown in FIG. 1 by a dotted line). Moreover, such wire bonding error may lead to short circuit and even jeopardize the entire semiconductor package.

Furthermore, referring to FIG. 2, another known layout of finger pads on a substrate is disclosed in U.S. Pat. No. 5,444,303, which is capable of reducing the length of bonding wires. In such prior-art layout, a plurality of finger pads 21 are disposed in rows, wherein the finger pads 21 are trapezium-shaped or reverse trapezium-shaped, with one longer side thereof parallel to an one shorter side thereof. Moreover, the longer side of one of the finger pads 21 may be closer to the chip 22, whereas the longer side of the one of the adjacent finger pads 21 may have the longer side further from the chip 22. In addition, a plurality of bonding wires 23 are employed for electrically connecting bonding pads 222 on the chip 22 to the finger pads 21 on the substrate.

Similar to the foregoing, the technique disclosed herein may reduce the pitch distance between the finger pads. However, in practical implementation, because the minimum width of a finger pad must be larger than or equal to 150 μm to allow the bonding wires to be bonded thereto, configurations of the prior art can only allow the bonding wires to be bonded to the wide end of the prior-art finger pad, and not to the narrow end. In other words, application of the prior art causes problems of insufficient bonding area and thus increases difficulty of the wire bonding process, thereby making the prior-art techniques infeasible for the industry.

Accordingly, a need still remains for developing a semiconductor substrate that can reduce pitch between the finger pads without mistakenly recognizing lead traces as finger pads and forming incorrect bonding during the wire bonding process, and solve the problem of insufficient wire bonding area.

Solutions to these problems have been long sought but prior developments have not taught or suggested any solutions and, thus, solutions to these problems have long eluded those skilled in the art.

### SUMMARY OF THE INVENTION

In light of the foregoing drawbacks of the prior art, a primary objective of the present invention is to provide a semiconductor substrate, which can effectively reduce pitches between finger pads.

Another objective of the present invention is to provide a semiconductor substrate, which can prevent any bond wire from erroneously bonding to a lead trace or to a non-targeted finger pad.

A further objective of the present invention is to provide a semiconductor substrate, which can increase the density of the bonding wires.

In order to achieve the foregoing and other objectives, a semiconductor substrate disclosed in the present invention comprises a body and a plurality of finger pads formed on the body, wherein each of the finger pads has two outwardly expanding portions and a connecting portion formed therebetween. Furthermore, the finger pads are staggeredly distributed on the body in a manner that the connecting portion of one of the finger pads is disposed in position corresponding to one of the expanding portions of an adjacent one of the finger pads. The bonding pads may be 8-shaped or I-shaped.

In other words, because each of the finger pads of the present invention has the connecting portion configured to fit with one of the expanding portions of an adjacent one of the finger pads, the finger pads can be staggered on the body of the semiconductor substrate in a horizontal direction and/or a vertical direction, thereby reducing horizontal and/or vertical pitches between the finger pads drastically. Furthermore, the outwardly expanding portions of the finger pads of the present invention can provide sufficient bonding areas for bonding wires to be bonded thereto, thereby overcoming problems of having insufficient bonding areas for electrically connecting the finger pads to a semiconductor chip via bonding wires, as well as reducing complexity of a wire bonding process. Moreover, the shape of the expanding portions of the finger pads may be configured to be significantly different from the shape of lead traces coupled thereto, so as to prevent a bonder from mistakenly recognizing the lead traces as another finger pads during a wire bonding process, thereby avoiding occurrences of wire bonding errors.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic view showing a prior-art layout of finger pads according to U.S. Pat. No. 5,898,213;

FIGS. 2 (PRIOR ART) is a schematic view showing a layout of finger pads according to U.S. Pat. No. 5,444,303;

FIG. 3 is a schematic planar view showing finger pads on a semiconductor substrate according to a first preferred embodiment of the present invention;

FIG. 4 is a schematic planar view of a semiconductor substrate that is attached and electrically connected to a semiconductor chip in accordance with the present invention; and

FIG. 5 is a schematic planar view showing finger pads on a semiconductor substrate according to a second preferred embodiment of the present invention.

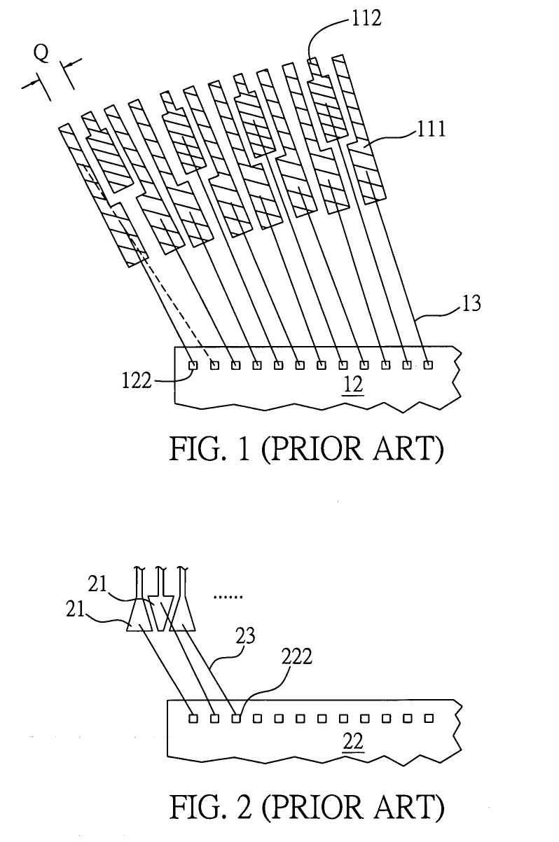

### DETAILED DESCRIPTION OF THE PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the “horizontal” as just defined. Terms, such as “on”, “above”, “below”, “bottom”, “top”, “side” (as in “sidewall”), “higher”, “lower”, “upper”, “over”, and “under”, are defined with respect to the horizontal plane.

### First Preferred Embodiment

Referring to FIG. 3, a schematic view of finger pads of a semiconductor substrate of the present invention is shown. The semiconductor substrate is formed by a body 30 and a plurality of finger pads 31 formed on the body 30. Each of the finger pads 31 has two expanding portions 311 and a connecting portion 312 formed therebetween. Furthermore, the finger pads 31 are staggeredly distributed on the body 30 in a manner that the connecting portion 312 of one of the fingers pads 31 is disposed in position corresponding to one of the expanding portions 311 of an adjacent one of the finger pads 31. To be more specific, the connecting portion 312 of one of the finger pads 32 is positioned between the expanding portions 311 of two adjacent finger pads 31.

The body 30 of the semiconductor substrate may be an insulation layer or an insulation layer having stacked circuit layers formed therein. For example, the insulation layer may be made of a material selected from the group consisting of glass fiber, epoxy, polyimide, flame-resistance resin (e.g. FR4 resin), and BT (bismaleimide triazine) resin. In addition, the body 30 has a plurality of lead traces 34 formed thereon, allowing one of the expanding portions 311 of each finger pad 31 to be electrically connected to a corresponding one of the lead traces 34.

In a first embodiment, each of the finger pads 31 is 8-shaped. Each finger pad 31 thus has two rounded portions 311 and a narrowed portion 312 formed therebetween. Accordingly, the narrowed portion 312 allows a space to be formed between the two rounded portions 311 interconnected by the narrowed portion 312, such that one of the rounded portions 311 of an adjacent one of the finger pads 31 can fit into the space of one of the finger pads 31. As a result, the pitch between any two adjacent finger pads 31 can be effectively reduced while maintaining a sufficient bonding area for each of the finger pads 31. In other words, the finger pads 31 are staggeredly distributed on the body 30 and the staggered pattern may be configured on a surface of the body 30 in a horizontal direction and/or a vertical direction to effectively reduce the horizontal and/or the vertical pitches between any two adjacent finger pads 31. Therefore, a fine-pitch package can be obtained.

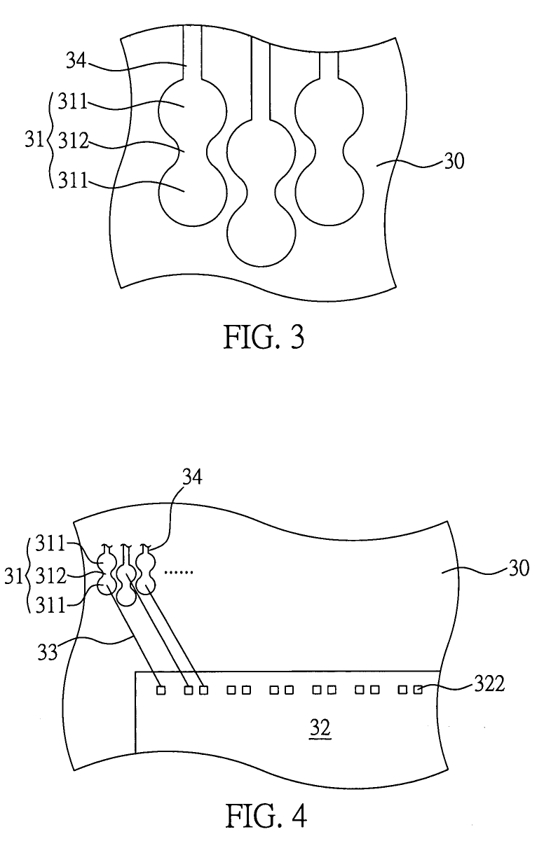

Referring to FIG. 4, at least a semiconductor chip 32 is attached to the semiconductor substrate depicted in FIG. 3 and formed with a plurality of bonding pads 322 thereon. Furthermore, by performing a wire bonding process, a plurality of bonding wires 33 are formed for electrically connecting the bonding pads 322 of the semiconductor chip 32 to the finger pads 31 on the body 30 that are distributed corresponding to the periphery of the semiconductor chip 32. As shown in FIG. 4, arrangements and designs of the present invention allow the outwardly expanding portions 311 of each of the finger pads 31 to provide a sufficient bonding area for the bonding wires 33 to be bonded to each of the finger pads 31. In addition, each bonding wire 33 may be selectively bonded to any one of the expanding portions 311 of each of the finger pad 31, so as to facilitate the wire bonding process. Moreover, the expanding portions 311 of the finger pads 31 is configured to be distinctive in shape from the lead traces 34 coupled to the expanding portions 311, so as to prevent a bonder from mistakenly recognizing the lead trace 34 as another finger pad 31 during the wire bonding process, thereby avoiding occurrences of wire bonding errors.

### Second Preferred Embodiment

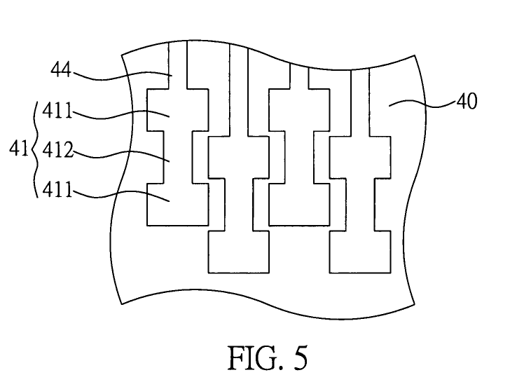

Referring to FIG. 5, a schematic planar view of finger pads of a semiconductor substrate according to a second preferred embodiment of the present invention is shown.

The semiconductor substrate of the second embodiment is substantially similar to that of the foregoing embodiment. However, one of the major differences between these two embodiments is that the finger pads 41 formed on the body 40 are I-shaped. Likewise, each of the I-shaped finger pads 41 comprises two squarely expanding portions 411 and a stripped portion 412 formed therebetween. The stripped portion 412 thus allows a space to be formed between the two squarely expanding portions 411, such that the squarely expanding portions 411 of an adjacent one of the finger pads 41 can fit into the space of one of the finger pads 41.

To be concluded from the above, each of the finger pads of the present invention comprises two expanding portions and a connecting portion formed therebetween, wherein the shape of the connecting portion can be configured or modified to adapt the expanding portions of an adjacent one of the finger pads. As a result, the finger pads can be staggeredly distributed on the body of the substrate in a manner that one of the expanding portions of one of the finger pads is disposed in position corresponding to the connecting portion of an adjacent one of the finger pads. Furthermore, the staggered pattern may be configured on a surface of the substrate body in a horizontal direction and/or a vertical direction to effectively reduce the horizontal and/or the vertical pitches between any two adjacent finger pads, so as to form a fine-pitch package.

Additionally, because the finger pads are formed with the outwardly expanding portions, the outwardly expanding portions can provide a sufficient bonding area for the bonding wire to be bonded thereto. This thereby overcomes problems of having insufficient bonding areas for the bonding wires to be bonded thereto in prior arts, as well as reduces complexity of the wire bonding process. Moreover, the expanding portions of the finger pads can be configured to be highly distinguishable in shape from the lead traces coupled thereto, so as to prevent a bonder from mistakenly recognizing the lead traces as another finger pads during the wire bonding process, thereby avoiding occurrences of wire bonding errors.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A semiconductor substrate, comprising:
a body; and
a plurality of finger pads formed on the body, each of the finger pads having two expanding portions and a connecting portion formed therebetween, wherein the finger pads are staggeredly distributed on the body in a manner that the connecting portion of one of the finger pads is disposed in position corresponding to one of the expanding portions of an adjacent one of the finger pads.

2. The semiconductor substrate of claim 1, wherein the body of the semiconductor substrate is made of one of an insulation layer and an insulation layer having stacked circuit layers, and further comprises a plurality of lead traces formed thereon and coupled to the finger pads.

3. The semiconductor substrate of claim 1, wherein the finger pads are 8-shaped to have two rounded portions and a narrowed portion.

4. The semiconductor substrate of claim 1, wherein the finger pads are I-shaped.

5. The semiconductor substrate of claim 1, wherein the finger pads are staggeredly distributed on the body of the semiconductor substrate in a manner that one of the expanding portions of one of the finger pads is disposed in position between the two expanding portions of an adjacent one of the finger pads.

6. The semiconductor substrate of claim 1, further comprising at least one semiconductor chip mounted thereon, wherein the semiconductor chip is formed with a plurality of bonding pads, and wherein the bonding pads are electrically connected to the finger pads of the semiconductor substrate that are disposed in position corresponding to a periphery of the semiconductor chip by means of bonding wires.

7. The semiconductor substrate of claim 6, wherein each of the bonding wires is bonded to one of the expanding portions of each of the finger pads.
